(19) United States
(12) Patent Application Publication
(10) Pub. No.: US 2011/0079849 A1
(43) Pub. Date: Apr. 7, 2011

(54) LATERAL-DIFFUSION METAL-OXIDE-SEMICONDUCTOR DEVICE

(76) Inventors: Ting-Zhou Yan, Kaohsiung County (TW); Bo-Jui Huang, Hsinchu City (TW); Chia-Kang Lin, Miaoli County (TW); Hong-Ze Lin, Hsinchu City (TW)

(21) Appl. No.: 12/573,892

(22) Filed: Oct. 6, 2009

(51) Int. Cl. H01L 29/78

(52) U.S. Cl. 257/343; 257/E29.256

(57) ABSTRACT

A lateral-diffusion metal-oxide-semiconductor device includes a source in a racetrack shaped active area, a first field oxide region isolating and surrounding the racetrack shaped active area, a racetrack shaped gate surrounding the source, and a drain disposed at one side of the gate opposite to the source. The source includes a P+ doping region in a P well and an N+ doping region butting on the P+ doping region.

### BACKGROUND OF THE INVENTION

1. Field of the Invention

The present invention relates generally to a high-voltage semiconductor device. More particularly, the present invention relates to a lateral-diffusion metal-oxide-semiconductor (LDMOS) device with reduced on-resistance (Rₒₙ).

2. Description of the Prior Art

Controllers, memories, circuits of low-voltage operation and power devices of high-voltage operation have been largely integrated together to achieve a single-chip system. The power device, such as vertical double-diffusion metal-oxide-semiconductor (VDMOS), insulated gate bipolar transistor (IGBT) or lateral diffusion MOS (LDMOS), has been employed to increase power switching efficiency and decrease the loss of energy resources. It is often required that the switching transistors withstand high breakdown voltages and operate at a low on-resistance.

Double diffuse drain (DDD) technology has been extensively applied to the source/drain (S/D) in order to provide a higher breakdown voltage. The DDD structure suppresses the hot electron effect caused by the short channel of the MOS transistor to further avoid electrical breakdown of the source/drain under high operational voltages. The LDMOS transistors are particularly prevalent because they can operate with a high efficiency and their planar structure allows for easy integration on a semiconductor die with other circuitry.

FIG. 1 is a schematic, cross-sectional diagram showing a conventional LDMOS transistor device. As shown in FIG. 1, the conventional LDMOS transistor device 10, which is formed on a semiconductor substrate 12, includes a source 14, a gate 16 and a drain 18. The source comprises a P+ doping region 21 in a P well 20. The P+ doping region 21 butts on an N+ doping region 22 that is also formed in the P well 20. The drain 18 is comprised of an N+ doping region 31 in an N well 30 and is approximately situated at a center area of the symmetric structure of the conventional LDMOS transistor device 10. The drain 18 is a common drain.

The gate 16 of the conventional LDMOS transistor device 10 is formed on a gate dielectric layer 40 and extends to a field oxide layer 42 that is formed by conventional local oxidation of silicon (LOCOS) methods. Typically, an N type drift region 36 is formed underneath the field oxide layer 42 within the N well 30. A P+ guard ring region 50, which is formed in a P well 52, is provided along the periphery of the conventional LDMOS transistor device 10. Another field oxide layer 44 is provided between the P+ guard ring region 50 and the N+ doping region 31.

It is desired in this industry to provide an improved LDMOS transistor device with reduced on-resistance (Rₒₙ).

### SUMMARY OF THE INVENTION

One objective of the present invention is to provide a lateral-diffusion metal-oxide-semiconductor (LDMOS) device with reduced Rₒₙ and better electrical performance.

According to the claimed invention, in one aspect, a lateral-diffusion metal-oxide-semiconductor device includes a source in a racetrack shaped active area, a first field oxide region isolating and surrounding the racetrack shaped active area, a racetrack shaped gate surrounding the source, and a drain disposed at one side of the gate opposite to the source. The source includes a P+ doping region in a P well and an N+ doping region butting on the P+ doping region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram showing a conventional LDMOS transistor device.

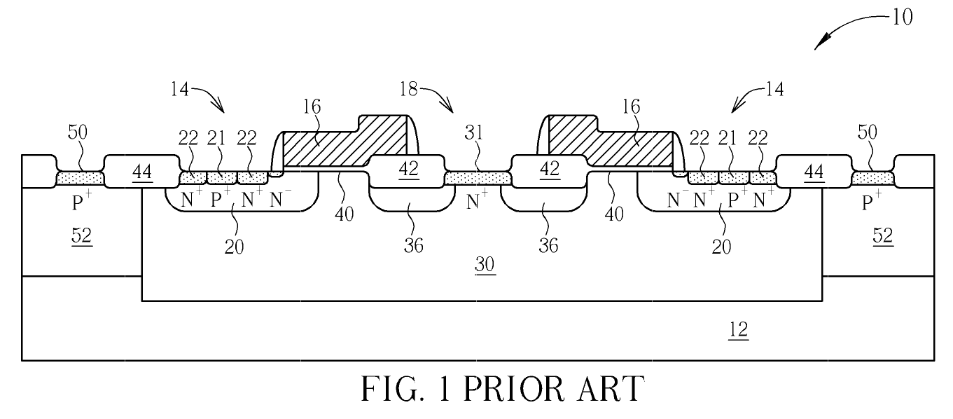

FIG. 2 is a schematic top view of the racetrack shaped layout of a LDNMOS transistor device in accordance with one preferred embodiment of this invention.

FIG. 3 is a schematic, cross-sectional diagram taken along line I-I′ of FIG. 2.

### DETAILED DESCRIPTION

The present invention has been particularly shown and described with respect to certain embodiments and specific features thereof. The embodiments set forth hereinbelow are to be taken as illustrative rather than limiting. It should be readily apparent to those of ordinary skill in the art that various changes and modifications in form and detail may be made without departing from the spirit and scope of the invention. The preferred embodiment of the present invention pertains to a lateral-diffusion N-type metal-oxide-semiconductor (LDNMOS) structure and layout thereof, which is particularly suited for power management integrated circuit (PMIC) applications.

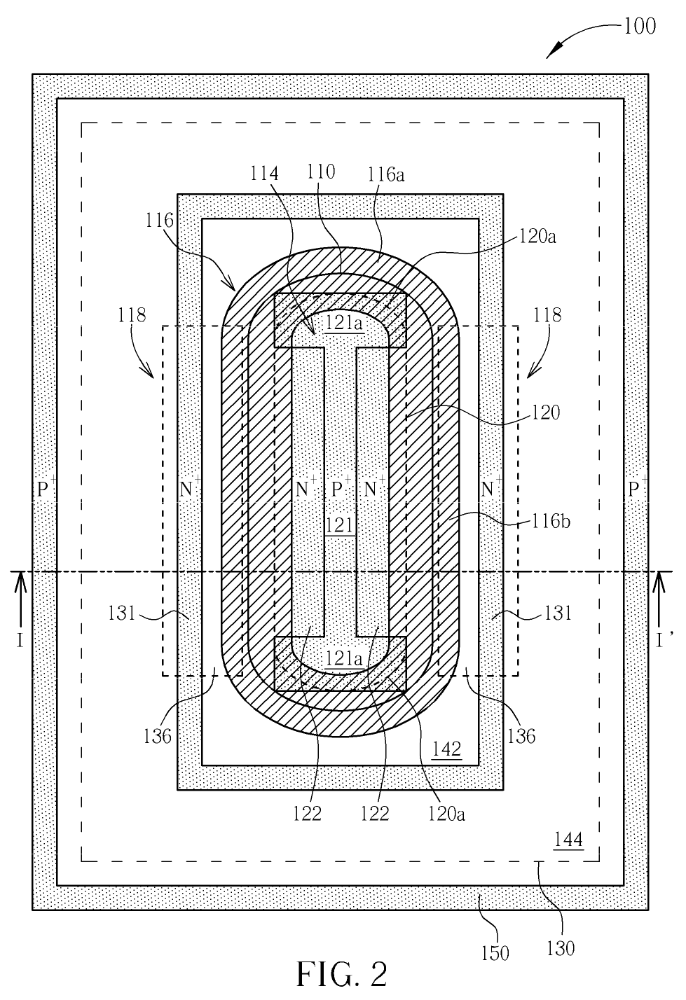

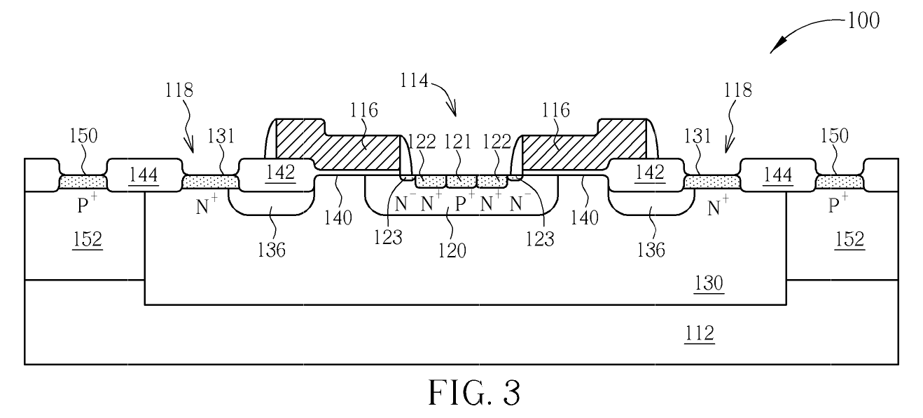

Please refer to FIG. 2 and FIG. 3. FIG. 2 is a schematic top view of the racetrack shaped layout of a LDNMOS transistor device in accordance with one preferred embodiment of this invention. FIG. 3 is a schematic, cross-sectional diagram taken along line I-I′ of FIG. 2. As shown in FIG. 2 and FIG. 3, the LDNMOS transistor device 100 according to this invention is fabricated on a semiconductor substrate 112. The LDNMOS transistor device 100 comprises a source 114, a gate 116 and a drain 118. The source 114 comprises a P+ doping region 121 that is formed in a P well 120. The P+ doping region 121 is sandwiched by N+ doping regions 122 butting on the P+ doping region 121. The N+ doping regions 122 are also formed in the P well 120. The LDNMOS transistor device 100 may further comprise a lightly doped drain (LDD) region 123 at one side of each of the N+ doping regions 122 opposite to the P+ doping region 121. The LDD region 123 is also part of the source 114.

According to the preferred embodiment of this invention, the source 114 is situated at the center area of the racetrack shaped layout of the LDNMOS transistor device 100 when viewed from above to form a common source configuration. The source 114, the P+ doping region 121, the N+ doping regions 122 and the P well 120 are formed in an isolated active area 110 that is also racetrack shaped when viewed from above. The preferred embodiment of this invention features that the P+ doping region 121 has an outline that is similar to a dog bone. The dog bone shaped P+ doping region 121 has two distal hammerheads 121a that are wide enough to cover or block the corresponding curved areas 120a of the P well 120, as best seen in FIG. 2.

According to the preferred embodiment of this invention, the drain 118 of the LDNMOS transistor device 100 is comprised of an N+ doping region 131 that is implanted into an N well 130. The N well 130 is preferably a high-voltage deep N well. The present invention LDNMOS transistor device 100 also features that the N+ doping region 131 is an annular shaped diffusion region that is disposed along the periphery of the symmetric structure of the LDNMOS transistor device 100. As best seen in FIG. 2, the N+ doping region 131 surrounds the racetrack shaped active area 110 and the source 114 formed in the active area 110.

According to the preferred embodiment of this invention, the gate 116 of the LDNMOS transistor device 100 is formed on a gate dielectric layer 140 and extends above the a field oxide layer 142 that is adjacent to the drain 118. The field oxide layer 142 may be formed by conventional LOCOS methods. As best seen in FIG. 2, the field oxide layer 142 is formed between the active area 110 and the annular N+ doping region 131. The gate 116 may comprise polysilicon, metal or metal silicide. It is another feature of the present invention LDNMOS transistor device 100 that the gate 116 is also racetrack shaped and has a closed loop layout that surrounds the source 114. As specifically indicated in FIG. 2, the gate 116 has curved regions 116a and rectilinear regions 116b.

According to the preferred embodiment of this invention, an N drift region 136 may be formed in the N well 130 underneath the field oxide layer 142. The LDNMOS transistor device 100 may further include an annular P+ doping region 150 that is preferably formed in a P well 152. The annular P+ doping region 150 functions as a guard ring of the LDNMOS transistor device 100. A field oxide layer 144 is formed between the annular P+ doping region 150 and the N+ doping region 131.

It is advantageous to use the present invention LDNMOS transistor device 100 because it provides lower Rₒₙ under the same cell pitch and fabrication process node. It has been experimentally found that the Rₒₙ of the present invention LDNMOS transistor device 100 can be as low as about 78 mΩ*mm² comparing to the conventional LDNMOS transistor device with Rₒₙ of about 90 mΩ*mm². In addition, the present invention LDNMOS transistor device 100 is able to provide robust safe operating area (SOA), and in one aspect, the cell pitch may be reduced to gain even lower Rₒₙ of the present invention LDNMOS transistor device 100. Further, the present invention LDNMOS transistor device 100 presents higher breakdown voltage (BVdss). Furthermore, the high side endurance of the present invention LDNMOS transistor device 100 is significantly improved, for example, from 30V to 41V.

Those skilled in the art will readily observe that numerous modifications and alterations of the device and method may be made while retaining the teachings of the invention.

What is claimed is:

1. A lateral-diffusion metal-oxide-semiconductor (LDMOS) device, comprising:
a source in a racetrack shaped active area, the source comprising an N+ doping region and a P+ doping region in a P well;
a first field oxide layer surrounding the racetrack shaped active area;
a racetrack shaped gate surrounding the source; and
a drain at an outer side of the racetrack shaped gate.

2. The LDMOS device according to claim 1 wherein the source is a common source.

3. The LDMOS device according to claim 1 wherein the N+ doping region butts on the P+ doping region.

4. The LDMOS device according to claim 1 wherein the P+ doping region of the source has a dog bone shaped layout.

5. The LDMOS device according to claim 4 wherein the P+ doping region has two distal hammerheads that are wide enough to block corresponding curved areas of the P well.

6. The LDMOS device according to claim 1 wherein the gate extends above the first field oxide layer.

7. The LDMOS device according to claim 1 wherein the gate has curved regions and rectilinear regions.

8. The LDMOS device according to claim 1 wherein the drain is comprised of an annular shaped diffusion region.

9. The LDMOS device according to claim 8 wherein the first field oxide layer is between the annular shaped diffusion region and the racetrack shaped active area.

10. The LDMOS device according to claim 1 wherein the P well, the first field oxide layer and the drain are formed in an N well.

11. The LDMOS device according to claim 10 wherein an N drift region is formed in the N well underneath the first field oxide layer.

12. The LDMOS device according to claim 1 further comprising an annular P+ doping region acting as a guard ring.

13. The LDMOS device according to claim 12 wherein a second field oxide layer is formed between the annular P+ doping region and the drain.
